(19) United States
(12) Patent Application Publication
(10) Pub. No.: US 2026/0079631 A1
(43) Pub. Date: Mar. 19, 2026

(54) MEMORY DEVICE HAVING IMPROVED CALCULATION ACCURACY OF OPTIMAL READ LEVEL AND OPERATING METHOD OF THE MEMORY DEVICE

(71) Applicant: Samsung Electronics Co., Ltd., Suwon-si (KR)

(72) Inventors: Sehwan PARK, Suwon-si (KR); Sangsoo PARK, Suwon-si (KR); Jinyoung KIM, Suwon-si (KR); Eunhyang PARK, Suwon-si (KR)

(73) Assignee: Samsung Electronics Co., Ltd., Suwon-si (KR)

(21) Appl. No.: 19/280,645

(22) Filed: Jul. 25, 2025

(30) Foreign Application Priority Data
Sep. 13, 2024 (KR) 10-2024-0126188

(51) Int. Cl. G06F 3/06

(52) U.S. Cl. CPC G06F 3/0619; G06F 3/0659; G06F 3/0679

(57) ABSTRACT

Provided is a memory device including a memory cell array including a plurality of cell areas, and a control logic configured to control a calculation operation for an appropriate read level, based on searching for a valley of threshold voltage distributions, in response to an error occurring in a read operation on the cell areas. The control logic, based on a counting operation on data read by using the plurality of read levels, is configured to calculate first through N^{th} counting values respectively corresponding to first through N^{th} read levels, calculate a crossing point of at least two linear functions modeled by substituting the first through N^{th} read levels as inputs and the first through N^{th} counting values as outputs, and calculate the appropriate read level based on at least one of the read level and a valley height corresponding to a coordinate value of the crossing point.

### CROSS-REFERENCE TO RELATED APPLICATION

This application is based on and claims ranking under 35 U.S. C. § 119 to Korean Patent Application No. 10-2024-0126188, filed on Sep. 13, 2024 in the Korean Intellectual Property office, the disclosure of which is incorporated by reference herein in its entirety.

### BACKGROUND

Some example embodiments relate to a memory device, and more particularly, to a memory device having improved calculation accuracy of a good or an optimal read level and/or an operating method of the memory device.

Flash memories, as non-volatile memories, may retain data stored therein even when power thereto is turned off. Storage devices including the flash memories such as solid-state drives (SSDs) and/or memory cards are widely used, and the storage devices are useful for storing or moving a large amount of data.

When the data storage capacity of flash memories is increased and/or the number of bits of data stored in each memory cell is increased, margins between a plurality of threshold voltage distributions may be reduced. When an error occurs during the data read process, a process of calculating a good or an optimal read level corresponding to a valley between threshold voltage distributions and re-reading data may be performed by using the calculated optimal read level. However, when the accuracy in the process of calculating the appropriate read level is not secured, an error may occur even in the process of re-reading data, and the error may be a factor causing reliability deterioration of data.

### SUMMARY

Some example embodiments may provide a memory device having improved read reliability of data by improving calculation accuracy of a read level, and/or an operating method of the memory device.

According to some example embodiments, there is provided a memory device including a memory cell array including a plurality of cell areas, wherein memory cells of each of the cell areas are configured to be in a plurality of threshold voltage distributions, and a control logic configured to control a calculation operation for an appropriate read level, based on searching for a valley of the threshold voltage distributions, in response to an error occurring in a read operation on the cell areas. The control logic, based on a counting operation on data read by using the plurality of read levels, is configured to calculate first through N^{th} counting values respectively corresponding to first through N^{th} read levels, to calculate a crossing point of at least two linear functions modeled by substituting the first through N^{th} read levels as inputs and the first through N^{th} counting values as outputs, and to calculate the appropriate read level based on at least one of the read level and a valley height corresponding to a coordinate value of the crossing point (where N is an integer greater than or equal to 3).

Alternatively or additionally according to some example embodiments, there is provided an operating method of a memory device including, as an error exists in data read from a first cell area of a memory cell array, entering a valley search mode based on control by a memory controller, in relation to the first cell area, based on a counting operation on data read by using a plurality of read levels, calculating first through fourth counting values respectively corresponding to first through fourth read levels, modeling an M^{th}-order function based on at least some of the first through fourth read levels and the counting values corresponding thereto (where M is an integer equal to or greater than 2), modeling one linear function based on the first and second counting values respectively corresponding to the first and second read levels and the other linear function based on the third and fourth counting values respectively corresponding to the third and fourth read levels, and calculating an appropriate read level for the first cell area, by applying a compensation value calculated by calculation using the two linear functions, to a read level calculated by using the M^{th}-order function.

Alternatively or additionally according to some example embodiments,, there is provided a memory device including a memory cell array including a plurality of cell areas, wherein memory cells of each of the cell areas are configured to be in a plurality of threshold voltage distributions, and in response to an error occurring in a read operation on the cell areas, a control logic configured to control a calculation operation for an appropriate read level, based on searching for a valley of the threshold voltage distributions. The control logic is configured to calculate first through N^{th} counting values respectively corresponding to first through N^{th} read levels, based on a counting operation on data read by using a plurality of read levels, and to output a flag, based on a coordinate value of a crossing point of at least two linear functions modeled by substituting the first through N^{th} read levels as inputs and the first through N^{th} counting values as outputs (where N is an integer equal to or greater than 3), to a memory controller, the flag indicating a degree of deterioration of the threshold voltage distributions.

### BRIEF DESCRIPTION OF THE DRAWINGS

Some example embodiments will be more clearly understood from the following detailed description taken in conjunction with the accompanying drawings in which:

FIG. 1 is a block diagram of a memory system according to some example embodiments;

FIG. 2 is a block diagram of an example implementation of the memory device in FIG. 1;

FIG. 3 is a flowchart of an operating method of a memory system, according to some example embodiments;

FIG. 4 is a block diagram of an implementation example of a memory device, according to some example embodiments;

FIG. 5 illustrates graphs of modeling examples of cell count functions and graphs of an example of calculating a crossing point of linear functions;

FIG. 6 is a diagram of an example of calculating counting values corresponding to read levels;

FIGS. 7 through 10 are diagrams of a compensating operation on read levels, according to embodiments;

FIGS. 11A, 11B, and 12 are diagrams of examples of using signs and absolute values of slopes of linear functions in calculating the optimal read level;

FIGS. 13A, 13B, and 13C are diagrams of examples of compensation operations, based valley heights and slopes of linear functions;

FIGS. 14A, 14B, and 14C illustrate tables representing examples in which a data recovery policy is selectively applied according to information about a linear function;

FIGS. 15 and 16 are flowcharts of examples of operations of a memory system, according to some example embodiments illustrated in FIGS. 14A, 14B, and 14C;

FIG. 17 is a schematic diagram of a structure of a memory device, according to some example embodiments; and

FIG. 18 is a block diagram of an example in which a memory system according to the embodiments is applied to a solid state drive (SSD) system.

### DETAILED DESCRIPTION OF SOME EXAMPLE EMBODIMENTS

Hereinafter, some example embodiments will be described in detail with reference to the accompanying drawings.

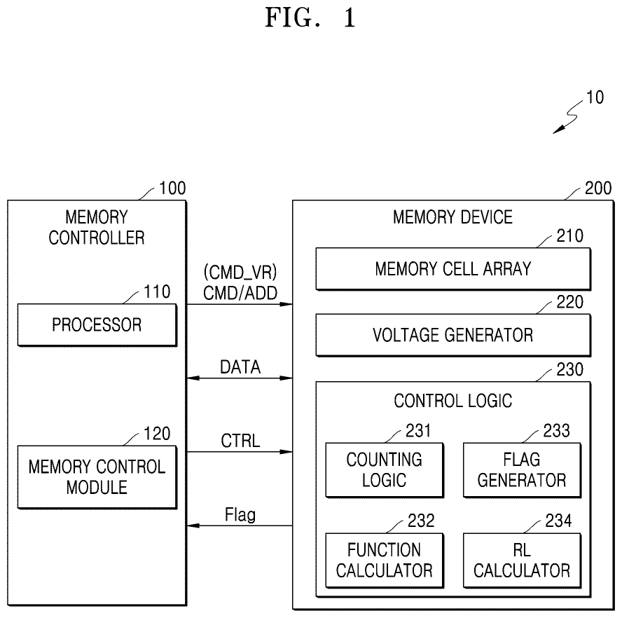

FIG. 1 is a block diagram of a memory system 10 according to some example embodiments.

Referring to FIG. 1, the memory system 10 may include a memory controller 100 and a memory device 200, and the memory controller 100 may include a processor 110 and a memory control module 120. In addition, the memory device 200 may include a memory cell array 210, a voltage generator 220, and a control logic 230, and in some example embodiments, the control logic 230 may include a counting logic 231, a function calculator 232, a flag generator 233, and a read level (RL) calculator 234. In the example of FIG. 1, the counting logic 231, the function calculator 232, the flag generator 233, and the RL calculator 234 are illustrated as provided in the control logic 230, but example embodiments are not limited thereto, and at least some of the components described above may also be implemented as separate components outside the control logic 230.

For example, the memory system 10 may communicate with a host via various interfaces, and as an example, the memory system 10 may communicate with the host via various interfaces, such as one or mor of a universal serial bus (USB) interface, a multi-media card (MMC) interface, an embedded MMC (eMMC) interface, a peripheral component interconnect (PCI) interface, a PCI-express (PCI-E) interface, an advanced technology attachment (ATA) interface, a serial-ATA interface, a parallel-ATA interface, a small computer system interface (SCSI), an enhanced small disk interface (ESDI), an integrated drive electronics (IDE) interface, Firewire, a universal flash storage (UFS) interface, and a non-volatile memory (NVM) express (NVMe) interface.

According to some example embodiments, the memory system 10 may include a non-volatile memory device. In some example embodiments, the memory system 10 may be implemented as being embedded in an electronic device or as a removable memory, and the memory system 10 may be implemented in various forms of, for example, one or more of an embedded universal flash storage (UFS) memory device, an eMMC, a solid state drive (SSD), a UFS memory card, a compact flash (CF) card, a secured digital (SD) card, a micro-SD card, a mini-SD card, an extreme digital (xD) card, or a memory stick. Alternatively or additionally, the memory system 10 may also be referred to as a storage device for storing data in a non-volatile manner.

The memory controller 100 may control the memory device 200 to read data DATA stored in the memory device 200 and/or to write data DATA to the memory device 200, in response to a write/read request from a host HOST. As an example, the processor 110 may control an overall operation inside the memory controller 100, and in addition, may control at least some, or up to an overall operation related with a memory operation of the memory device 200. The memory controller 100 may control one or more of the write, read and erase operations of the memory device 200 by providing a command/address CAM/ADD and a control signal CTRL to the memory device 200. The memory control module 120 may be implemented based on hardware, software, or a combination thereof, and may control a memory operation on the memory device 200. In some example embodiments, one or more errors occur and/or at least one uncorrectable error correction code (UECC) error occurs in the data read from the memory device 200, and the memory control module 120 may perform a control operation so that the memory device 200 restores the data based on various types of recovery policies.

The memory cell array 210 may include a plurality of memory cells, and the plurality of memory cells may include, for example, flash memory cells. Hereinafter, some example embodiments are described in detail for the case, as an example, in which the plurality of memory cells include NAND flash memory cells. However, example embodiments are not limited thereto. In some example embodiments, the plurality of memory cells may include resistive memory cells, such as one or more of resistive read-only memory (RAM) (RRAM), phase-change RAM (PRAM), and magneto-resistive RAM (MRAM).

In some example embodiments, the memory cell array 210 may include a three-dimensional (3D) memory cell array, the 3D memory cell array may include a plurality of NAND strings, and each NAND string may include the memory cells respectively connected to the word lines vertically stacked on a substrate. However, example embodiments are not limited thereto, and in some example embodiments, the memory cell array 210 may alternatively or additionally include a two-dimensional (2D) memory cell array, and the 2D memory cell array may include the plurality of NAND strings arranged in row and column directions.

When a read command requesting a read of data from the memory controller 100 is provided to the memory device 200, the read operation may be performed based on control by the control logic 230. As an example, when each memory cell stores a plurality of bits, the memory cells of the memory cell array 210 may include a plurality of threshold voltage distributions, and data including two or more bits may be read from each memory cell.

The voltage generator 220 may generate various voltages used in the memory device 200, and as an example, a program voltage for a program operation and a read voltage for the read operation may be generated. Alternatively or additionally, the voltage generator 220 may variously control levels of the program voltage and the read voltage, based on control by the control logic 230. For example, the voltage generator 220 may provide the read voltage having various levels for identifying the plurality of threshold voltage distributions. Alternatively or additionally, when the UECC error occurs in the read process of data, the voltage generator 220 may generate a read voltage with a level thereof adjusted based on control by the control logic 230. As an example, when an error is detected or the UECC error occurs in the data read from the cell area of a read unit (for example, memory cells of a page unit), a series of operations for calculating an appropriate read level, e.g., a good or optimal read level of the cell area may be performed, and the voltage generator 220 may generate a read voltage having an optimal level, based on control by the control logic 230.

The control logic 230 may control a some or all, e.g., up to a whole operation of the memory device 200, and as an example, based on the command/address CMD/ADDR, and the control signal CTRL, which are received from the memory controller 100, the control logic 230 may output various internal control signals for programming data in the memory cell array 210 or reading data from the memory cell array 210. Alternatively or additionally, the control logic 230 may also output a voltage control signal (not illustrated) for controlling levels of various voltages, which are output by the voltage generator 220 in relation with the program operation, the read operation, and the erase operation.

When the UECC error occurs, assuming that an operation of calculating the optimal read level is performed, the memory controller 100 may perform a detection or a detection/correction operation on the data received from the memory device 200, and when the UECC error occurs, the memory controller 100 may output a command such as a pre-defined command (for example, a valley search read command CMD_VR), and the memory device 200 may perform a series of operations for calculating the optimal read level in response to the valley search read command CMD_VR. Alternatively or additionally, the memory device 200 may retry a read operation on a cell area where an error has occurred, based on the calculated optimal read level. Because the calculation operation of the optimal read level may be performed by the memory device 200, the calculation operation may be referred to as an on-chip valley search operation.

The optimal read level may be calculated based on counting values generated by performing a counting operation (that is, on-cell or off-cell counting) on read data by using multiple read levels. For example, a location of a valley between threshold voltage distributions may be determined by using a plurality of read levels and the counting values corresponding thereto, and the read level corresponding to the valley may be determined as the optimal read level.

As a method of calculating the optimal read level, the counting values corresponding to a plurality of different read levels may be calculated, and a cell count function may be modeled by substituting the calculated read levels and counting values as input and output, on a coordinate system where the read levels are defined as the x-axis and the counting values are defined as the y-axis. The cell count function may be modeled to have a shape approximate to the threshold voltage distributions of the memory cells, and for example, the cell count function may be modeled as a polynomial such as a quadratic, tertiary, or high-order function, and may be based on a Lagrange polynomial. As an example, an x value corresponding to the minimum Y value in a high-order function may be calculated, and the optimal read level may be calculated based on the x value.

According to some example embodiments, to improve the calculation accuracy of the optimal read level, the control logic 230 may model two or more linear functions, based on the read levels and the counting values corresponding thereto, and may generate a compensation value for increasing the calculation accuracy of the optimal read level, based on the modeled linear functions. For example, the optimal read level may be calculated based on the valley search by using a plurality of read levels and counting values, and the compensation value calculated based on the linear functions described above may be applied to the optimal read level that has been calculated, based on the valley search.

For example, when the valley search is performed by using a high-order function technique, the optimal read level may be compensated by applying the compensation value, which is calculated based on the linear functions described above, to the optimal read level calculated based on the high-order function. For example, an error may occur in the read level calculated based on the cell count function modeled as a high-order function, compared to the actual optimal read level, and the optimal read level in which no error exists or the error is minimized may be calculated by using the compensation value calculated in some example embodiments. In the following example embodiments, in relation to the term definition, the optimal level calculated by using the valley search and/or the high-order function may be referred to as the read level, and a value which is obtained by applying the compensation value calculated by using the linear functions to the read level calculated by using the high-order function may be referred to as the optimal read level.

In an implementation example, the counting logic 231 may perform the counting operation on read data by using a plurality of read levels, and may calculate the counting value corresponding to each read level. In one non-limiting operation example, when an on-cell is counted, the number of on-cells may be counted from data read from a cell area of a certain read unit (for example, a page unit). For example, the number of on-cells for each of the two adjacent levels (a read level A and a read level B) may be determined, and the difference value between the determined number of on-cells may be calculated as a counting value corresponding to any one read level. For example, the level A, the level B, or any level between the level A and the level B may correspond to the read level corresponding to the calculated counting value. In some example embodiments, the counting logic 231 may calculate N counting values respectively corresponding to N read levels, and N is assumed to have a value equal to or greater than 3.

The function calculator 232 may model various cell count functions by using N read levels and N counting values corresponding thereto. For example, the function calculator 232 may model a high-order function (for example, a quadratic function) by using three read levels and three counting values corresponding thereto, and for example, the coefficients of the quadratic function may be calculated by substituting the read level into the x value and the counting value into the y value. Alternatively or additionally, the function calculator 232 may model at least two linear functions by using N read levels and N counting values. For example, each linear function may be modeled by using two read levels and two counting values corresponding thereto, and the read levels used to model one linear function may be different from the read levels used to model the other linear function.

Alternatively or additionally, the function calculator 232 may perform various calculation operations to determine the graph characteristics of modeled linear functions, and for example, may perform operations by using coefficients of linear functions. The function calculator 232 may calculate the sign and the absolute value of the slope of each linear function, and in addition, the function calculator 232 may calculate a crossing point of the two linear functions. The location of the crossing point may be approximate to the position of the valley between the threshold voltage distributions, and accordingly, in some example embodiments below, the y value of the crossing point of the linear functions may be referred to as a value corresponding to a valley height.

The flag generator 233 may generate and store a flag, based on at least one piece of information from the function calculator 232. As a non-limiting example, the flag may include one or more bits, and may indicate the degree of deterioration of the threshold voltage distribution of the memory cells. For example, the flag may be generated based on a value of the crossing point of linear functions, slope values of linear functions, etc. In some example embodiments, the memory device 200 may transmit the flag to the memory controller 100. For example, the memory device 200 may communicate with the memory controller 100 via various channels, and the memory controller 100 may output a status read command for reading the flag, to the memory device 200. In addition, the memory device 200 may output the flag, based on in-band communication of data channel, or the like, or may output the flag based on side-band communication.

A RL calculator 234 may calculate the optimal read level based on information from the function calculator 232. For example, the RL calculator 234 may receive information about a high-order function (for example, a quadratic function and/or a tertiary function) from the function calculator 232, and may calculate the read level based on the high-order function. Alternatively or additionally, the RL calculator 234 may calculate the compensation value by using at least one of signs of slopes of linear functions, absolute values of the slopes, and information about the crossing point of the linear functions, and may calculate the optimal read level by applying the compensation value to the read level that is calculated based on the high-order function. The memory device 200 may perform a re-reading operation based on the calculated optimal read level and accordingly, an error may be removed, or read data having the number of errors thereof reduced may be generated.

When noise is generated during the read process of memory cells or when threshold voltage distributions are changed to have an asymmetric form, the accuracy of the cell count function of the high-order function may be reduced. According to some example embodiments, one or more linear functions may be further modeled by using information used to model the existing high-order function (for example, a read level and a counting value), and because compensation values may be calculated based on the modeled linear functions, the accuracy in the calculation process of the optimal read level may be improved.

Alternatively or additionally, according to some example embodiments described above, interference between the memory cells may be increased due to process miniaturization of a memory device such as a NAND, and distances between threshold voltage distributions may be reduced according to an increase in the number of bits to be stored by each memory cell. Accordingly, the threshold voltage distribution characteristics may be reduced and/or a variation thereof may increase as the degree of integration of the memory device is increased, but the memory system 10 according to some example embodiments may calculate the optimal read level with high accuracy despite the noise environment and/or the high degree of integration.

In some example embodiments below, cases where high-order functions are modeled are illustrated in relation to calculation of the optimal read level, but the embodiments are not limited thereto. For example, the read level may be calculated based on a plurality of counting values, without performing a modeling of a high-order function, and a compensation value may also be applied to the calculated read level.

Alternatively or additionally, in some example embodiments, a read level is described as being calculated based on a high-order function, but it may be described that a default read level is predefined in relation to a read operation, and an offset value applied to the default read level is calculated based on the high-order function. In other words, the compensation value according to some example embodiments may also be applied to a value obtained by adding the default read level and the offset value.

On the other hand, in some example embodiments described above, the function calculator 232, the flag generator 233, and the RL calculator 234 are illustrated as separate components, but example embodiments are not limited thereto. Each of the function calculator 232, the flag generator 233, and the RL calculator 234 may be implemented, based on a hardware circuit, software, or a combination thereof. In addition, the components described above may correspond to configuration examples in which a series of operations according to the embodiment are classified based on a certain function, and when the series of operations are classified based on another function, other components may also be defined. For example, the memory device 200 may include a read level calculation module, and the read level calculation module may also be defined as including at least some of the counting logic 231, the function calculator 232, the flag generator 233, and the RL calculator 234.

On the other hand, in some example embodiments described above, an example is illustrated in which the counting operation and the read level calculation operation are generated in the memory device 200, but example embodiments are not limited thereto. For example, the memory device 200 may output data read based on a plurality of read levels to the memory controller 100, and as the memory controller 100 performs a counting operation, a function modeling operation, and a read level calculation operation, may calculate the optimal read level, and may also output information in relation to the calculated optimal read level to the memory device 200. In other words, the memory system 10 may be implemented so that modeling a linear function according to the embodiment and generating a compensation value based on the modeled linear function are performed on the side of the memory controller 100.

Each of the elements or functional blocks listed in FIG. 1 may communicate with any other elements or functional blocks listed in FIG. 1, to transmit and/or receive information across a bus such as but not limited to a wired and/or a wireless bus. The information may correspond to data and/or commands, and may be encoded in digital and/or analog format. The information may be sent serially and/or in a parallel manner, such as in a one-way and/or two-way and/or multi-way format such as a broadcast format; example embodiments are not limited thereto.

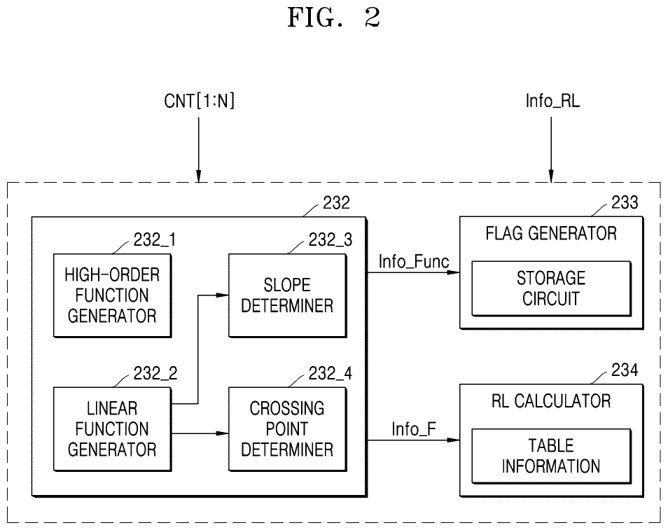

FIG. 2 is a block diagram of an example implementation of the memory device 230 in FIG. 1.

Referring to FIGS. 1 and 2, the function calculator 232 may include a high-order function generator 232_1, a linear function generator 232_2, a slope determiner 232_3, and a crossing point determiner 232_4. Assuming that the counting logic 231 generates N counting values CNT[1:N] corresponding to N read levels, the function calculator 232 may generate various pieces of information, based on N pieces of read level information Info_RL and the N counting values CNT[1:N] described above, and the high-order function generator 232_1 may model a cell count function for calculating the read level. As an example, the high-order function generator 232_1 may calculate coefficient values of the cell count function corresponding to a quadratic function, and by substituting three or more read levels into the x value and substituting counting values corresponding thereto, the coefficients of the quadratic function may be calculated. Alternatively or additionally, the high-order function generator 232_1 may also model a cell count function having a tertiary or higher order.

The linear function generator 232_2 may model a plurality of linear functions, and for example, may calculate respective coefficients of two linear functions. Each of the coefficients of a linear function may be calculated, by substituting two read levels into the x value and substituting the counting values corresponding thereto into the y value. In a non-limiting operation example, coefficients of one linear function may be calculated based on two read levels of the read level information Info_RL and two counting values corresponding thereto, and coefficients of the other linear function may be calculated based on two other read levels and two counting values corresponding thereto. Alternatively or additionally, when the read level information Info_RL includes three read levels, the coefficients of one linear function may be calculated based on two read levels, and the coefficients of the other linear function may be calculated based on any one of the two read levels and the other thereof.

The slope determiner 232_3 may determine a slope of each of two linear functions, and for example, may determine a sign of the slope and the absolute value of the slope. For example, the slope determiner 232_3 may determine a value related to a slope of each linear function, based on coefficient information from the linear function generator 232_2. In addition, the crossing point determiner 232_4 may determine a crossing point of two linear functions, and for example, may determine an x value and a y value of the crossing point, while the y value of the crossing point may have a value related to the valley height.

Each of the flag generator 233 and the RL calculator 234 may perform a particular function based on various pieces of information from the high-order function generator 232_1 and the linear function generator 232_2. For example, when information related to a modeled cell count function (for example, coefficient information) is defined as function information Info_Func, and various pieces of information such as a crossing point value calculated by using calculation on the modeled functions is defined as calculation information Info_F, each of the flag generator 233 and the RL calculator 234 may use at least one of the read level information Info_RL, the counting value CNT[1:N], the function information Info_Func, and the calculation information Info_F. The flag generator 233 may generate a flag which indicates the degree of deterioration of the threshold voltage distribution of the memory cells. Alternatively or additionally, the flag generator 233 may include a storage circuit storing the flag.

The RL calculator 234 may calculate the RL based on information related to a high-order function of the function information Info_Func, calculate the compensation value based on the function information Info_Func and/or the calculation information Info_F, and calculate the optimal read level by applying the compensation value to the read level. The RL calculator 234 may calculate the optimal read level by calculating the read level and the compensation value, and for example, may calculate the good or optimal read level by adding or subtracting to or from the read level. In some example embodiments, the RL calculator 234 may include table information storing the compensation values corresponding to various values of the calculation information Info_F, and calculate the compensation value based on table information.

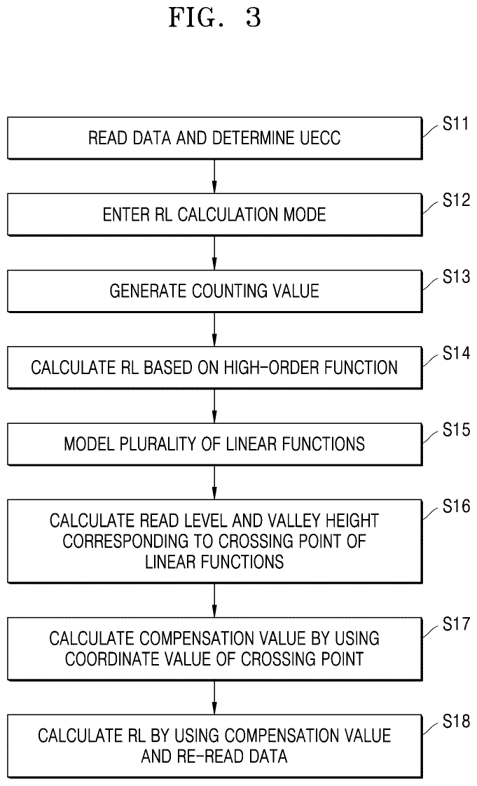

FIG. 3 is a flowchart of an operating method of the memory system 10, according to some example embodiments. Each of operations illustrated in the flowchart of FIG. 3 may include an operation performed by a memory controller or an operation performed by a memory device.

Referring to FIG. 3, the memory controller may read data from a memory device according to a read request of a host, and perform an error detection/correction on the read data. The memory controller may determine that the UECC has occurred, based on the error detection/correction operation (S11).

As the UECC has occurred, the memory controller may transmit a command directing re-reading of data based on the optimal read level to the memory device, and the memory device may enter a read level calculation mode to perform a series of operations (S12). For example, as described above, the memory device may perform a counting operation on the read data by using a plurality of read levels, and generate counting values corresponding to the plurality of read levels (S13). In some example embodiments, the memory device may model various types of cell count functions, based on the plurality of read levels and the counting values corresponding thereto, and for example, may calculate the read level based on a cell count function corresponding to a high-order function, such as a quadratic function and a tertiary function (S14).

In addition, according to some example embodiments, the memory device may model at least two linear functions, based on the plurality of read levels and counting values (S15). Assuming that two linear functions are modeled, the memory device may determine a crossing point of the two linear functions, based on calculation on the two linear functions, and may calculate a read level corresponding to an x value of the crossing point and a valley height corresponding to a y value of the crossing point (S16). The memory device may calculate a compensation value by using the read level and/or the valley height corresponding to the coordinate value of the crossing point (S17), and may calculate the optimal read level by applying the calculated compensation value to the calculated read level based on a quadratic function. In addition, the memory device may re-read data by using the calculated optimal read level (S18).

In FIG. 3, an example of calculating the compensation value based on the crossing point of two linear functions is illustrated, but example embodiments are not limited thereto, and the compensation value may also be calculated by using various information, such as a sign of a slope that may be calculated from the linear functions, and the absolute value of the slope.

Some operations listed in FIG. 3 may occur before, after, or concurrently with other operations listed in FIG. 3; in some example embodiments, some operations may be repeated and/or iterated. Example embodiments are not limited thereto.

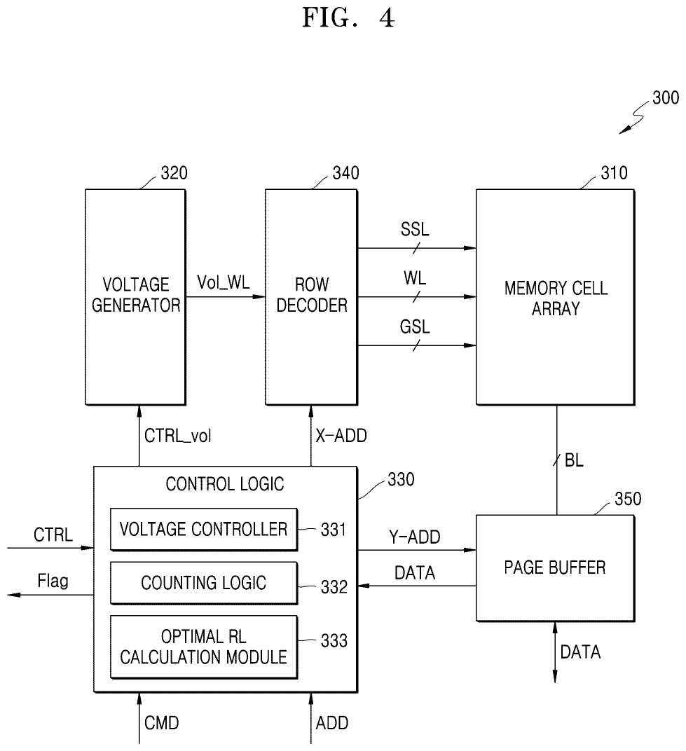

FIG. 4 is a block diagram of an implementation example of a memory device 300, according to some example embodiments.

Referring to FIG. 4, the memory device 300 may include a memory cell array 310, a voltage generator 320, a control logic 330, a row decoder 340, and a page buffer 350. The memory cell array 310 may be connected to the row decoder 340 via word lines WL, string select lines SSL, and ground select lines GSL, and may be connected to the page buffer 350 via the bit lines BL. Each of the memory cells may store one or more bits, and for example, each memory cell may correspond to a multi-level cell (MLC), a triple-level cell (TLC), or a quad-level cell (QLC), or may store a greater number of bits. In some example embodiments, the memory cell array 310 may be homogenous and include memory cells each having the same capacity per cell; alternatively, the memory cell array 310 may be heterogeneous and may include memory cells having different capacity per cell

The control logic 330 may output various internal control signals for controlling one or more of program, read, and erase operations of the memory cell array 310, based on a command/address CMD/ADD and a control signal CTRL received from the memory controller. As an example, the control logic 330 may include a voltage controller 331, output a voltage control signal CTRL_vol for controlling levels of various voltages generated by the voltage generator 320, provide a row address X-ADD to the row decoder 340, and provide a column address Y-ADD to the page buffer 350.

Based on the control by the control logic 330, the voltage generator 320 may output word line voltages Vol_WL having a plurality of read levels in relation to calculation of the optimal read level. In addition, when the optimal read level is calculated, the voltage generator 320 may output the word line voltage Vol_WL having the optimal read level, and the re-reading operation using the optimal read level may be performed.

According to some example embodiments, the control logic 330 may include a counting logic 332 and an optimal read level calculation module 333. For example, the counting logic 332 may perform a counting operation on the read data, based on each read level, and based on the result thereof, may generate a counting value indicating the number of memory cells corresponding to on-cells (or, off-cells). Based on the counting operation, N counting values respectively corresponding to N read levels may be generated, and the optimal read level calculation module 333 may use the plurality of read levels and the counting values corresponding thereto to calculate the appropriate or optimal read level used for the re-read operation.

The optimal read level calculation module 333 may include various components illustrated in FIG. 1. As an example, the optimal read level calculation module 333 may model one or more functions, and generate one or more pieces of information indicating characteristics of the modeled functions. For example, according to the embodiments described above, the optimal read level calculation module 333 may generate information related to a crossing point of a plurality of linear functions, and in addition, may generate various types of information, such as a slope sign and the absolute value of the slope of each linear function. In addition, the optimal read level calculation module 333 may generate, based on the various pieces of information described above, a flag indicating the degree of deterioration of the threshold voltage distribution, and the flag may be output to the memory controller. In addition, the optimal read level calculation module 333 may calculate the optimal read level based on the various pieces of information described above, and for example, by applying a compensation value generated based on a plurality of linear functions to the read level calculated based on a quadratic function or the like, errors may be eliminated or a reduced optimal read level may be calculated.

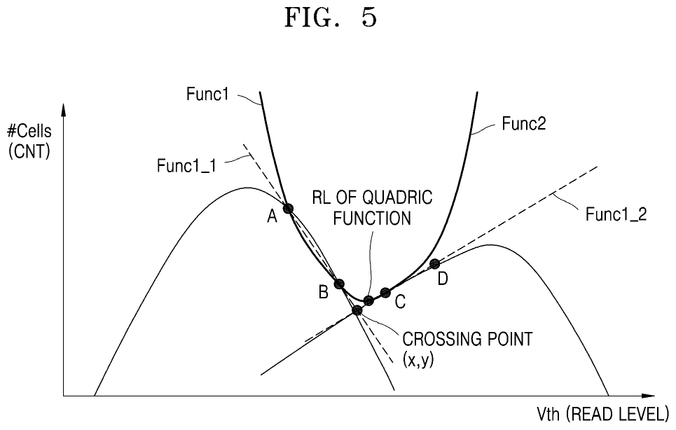

FIG. 5 illustrates graphs of modeling examples of cell count functions and graphs of an example of calculating a crossing point of linear functions.

As the characteristics of the threshold voltage distribution deteriorate, e.g., as a variation thereof increases, a case in which the adjacent threshold voltage distributions overlap may occur, and a plurality of functions may be modeled for calculating an appropriate, e.g., a good or sufficient or optimal read level. As an example, when the graph of FIG. 5 indicates the threshold voltage distribution, the x axis may indicate the threshold voltage level Vth, and the y axis may indicate a number of memory cells #Cells. In addition, when the graph of FIG. 5 indicates the cell count function, the x axis may indicate the read level, and the y axis may indicate counting values CNT.

Like the example of the threshold voltage distribution illustrated by the solid line, as the threshold voltage distribution deteriorate, the width of distribution may be widened or a variance or standard deviation thereof may increase, and in some example embodiments, the distribution may have an asymmetric shape. Based on a counting operation on read data by using a plurality of read levels, on the graph of the threshold voltage distribution, counting values corresponding to a plurality of read levels may be calculated, and as an example, in FIG. 5, the plurality of read levels and the counting values corresponding thereto may correspond to four coordinates A, B, C, and D. In addition, according to some example embodiments described above, a high-order function such as a high-order polynomial or high-degree function may be modeled, and for example, a quadratic function Func2 may be modeled, based on three read levels and counting values corresponding thereto, and or a tertiary function (not illustrated) may be modeled, based on four read levels and counting values corresponding thereto. The modeled high-order function may have a shape approximate to that of the threshold voltage distribution.

In some example embodiments, based on at least three read levels of the four coordinates A, B, C, D and counting values corresponding thereto, two linear functions Func1_1 and Func1_2 may be modeled. As an example, based on two coordinates A and B corresponding to relatively low read levels, one linear function may be modeled, and based on two coordinates C and D corresponding to relatively high read levels, one linear function may be modeled. Alternatively or additionally, the waveform represented by the two linear functions may have a shape approximate to some interval including the valley of the threshold voltage distributions.

Assuming that the read level is calculated by using the quadratic function Func2, in the quadratic function Func2, the x value of the coordinate, at which the y value is the minimum value, may be calculated as the read level RL. However, as illustrated in FIG. 5, when the characteristics of the threshold voltage distribution deteriorate, an error between the actual location of the valley of the threshold voltage distributions and the read level RL calculated by using the quadratic function Func2 may occur, and this error may indicate that the read level RL calculated from the quadratic function Func2 does not correspond to the actual optimal read level. According to some example embodiments, a good or optimal read level may be calculated by calculating a crossing point of two linear functions Func1_1 and Func1_2, calculating a compensation value by using the x value of the crossing point (or, a read level corresponding to the x value) and y value of the crossing point (or, the valley height), and applying the compensation value to the read level calculated from the quadratic function Func2. Alternatively or additionally, the slope value of each of two linear functions Func1_1 and Func1_2 may also be used for calculation of the compensation value.

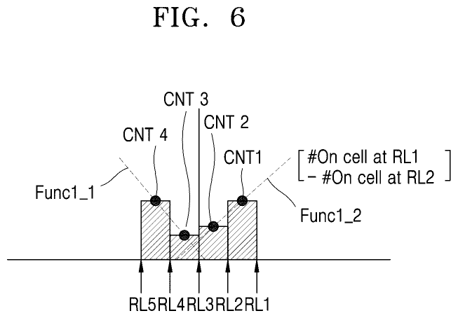

FIG. 6 is a diagram illustrating an example of calculating counting values corresponding to read levels. FIG. 6 illustrates first through fourth counting values CNT1 through CNT4 respectively corresponding to four read levels.

In some example embodiments, the counting value may be calculated as a difference value between the number of on cells (or, off cells) of any one read level and the number of on cells (or, off cells) of another read level. For example, the first counting value CNT1 may correspond to a value obtained by subtracting the number of on-cells of data read by using a second read level RL2, from the number of on-cells of data read by using a first read level RL1. Similarly, the second counting value CNT2 may correspond to a value obtained by subtracting the number of on-cells of data read by using a third read level RL3, from the number of on-cells of data read by using the second read level RL2.

Considering the threshold voltage distribution of memory cells, memory cells having the threshold voltage on one side (e.g., the left side) of a certain read level as a reference (or, when the threshold voltage is less than a read level) may correspond to on cells, and memory cells having the threshold voltage on another side (e.g., the right side) of a certain read level as a reference (or, when the threshold voltage is greater than a read level) may correspond to off cells. Accordingly, when a read operation is performed while the read level is lowered by a certain interval, the number of on cells may be calculated less than the case in which the read level is raised. Accordingly, each of the first through fourth counting values CNT1 through CNT4 illustrated in FIG. 6 may have a value equal to or greater than about 0.

On the other hand, when data is read by using read levels adjacent to the valley between threshold voltage distributions, the number of on-cells determined based on the counting operation may be the same as or similar to each other, and accordingly, the counting value may have a relatively small value. For example, second through fourth read levels RL2 through RL4 may be adjacent to a valley between threshold voltage distributions, and the second and third counting values CNT2 and CNT3 may have relatively small values.

In some example embodiments, a read level corresponding to a counting value may be variously defined. For example, any one of the first read level RL1 and the second read level RL2 may be defined as the read level corresponding to the first counting value CNT1. Alternatively, an arbitrary read level between the first read level RL1 and the second read level RL2 may be defined as the read level corresponding to the first counting value CNT1, or an average level of the first read level RL1 and the second read level RL2 may also be defined as the read level corresponding to the first counting value CNT1. In other words, in calculating N counting values, (N+1) read operations by using (N+1) read levels may be performed.

On the other hand, a high-order function may be modeled, based on first through fourth read levels RL1 through RL4 and first through fourth counting values CNT1 through CNT4. Because a quadratic function may be modeled or fitted based on three read levels, in an operation example, a read level may be calculated based on one quadratic function, or two or more quadratic functions may be modeled, and a read level may be calculated therefrom. Alternatively, a tertiary function may be modeled based on the four read levels, and the read level may also be calculated based on the tertiary function.

Alternatively or additionally, based on the first through fourth read levels RL1 through RL4 and the first through fourth counting values CNT1 through CNT4, a plurality of linear functions Func1_1 and Func1_2 may be modeled, and information related to each of the linear functions and information related to a crossing point of two linear functions may be generated. Alternatively or additionally, according to some example embodiments described above, based on information generated from the plurality of linear functions, a compensation value used for calculating the optimal read level may be calculated.

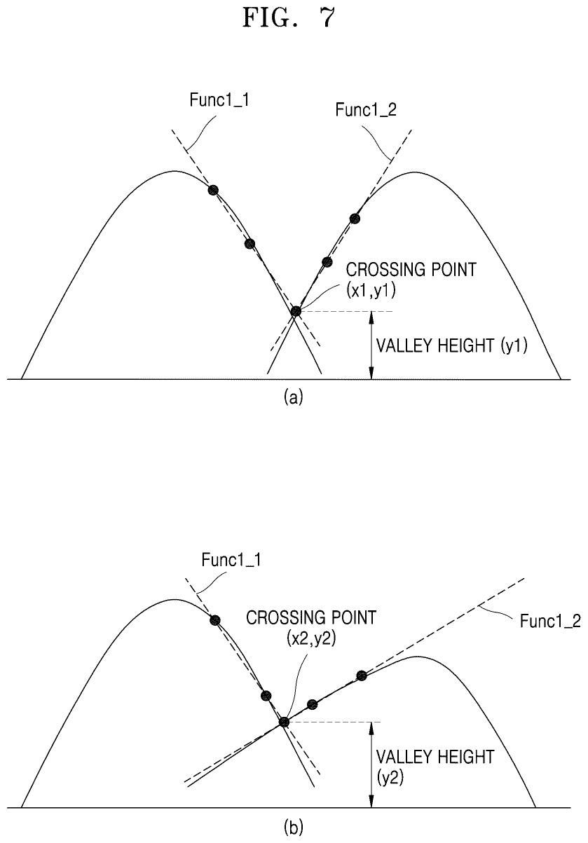

FIGS. 7 through 10 are diagrams of a compensating operation on read levels, according to embodiments.

FIG. 7 illustrates different cases in which the valley heights are calculated different. While FIG. 7(a) illustrates a case in which a coordinate value (x1, y1) of a crossing point of two linear functions Func1_1 and Func1_2 is calculated and a valley height y1 calculated from the coordinate value (x1, y1) has a relatively small value, FIG. 7(b) illustrates a case in which a coordinate value (x2, y2) of a crossing point of two linear functions Func1_1 and Func1_2 is calculated and a valley height y1 calculated from the coordinate value (x2, y2) has a relatively large value.

As an example, when the degree of deterioration of the threshold voltage distributions is relatively small, the valley height y1 may be calculated as relatively small as illustrated in FIG. 7(A), and accordingly, the compensation value calculated based on the linear functions Func1_1 and Func1_2 may be relatively small compared to the case of FIG. 7(B). On the other hand, when the degree of deterioration of the threshold voltage distributions is relatively large, the valley height y2 may be calculated as relatively large as illustrated in FIG. 7(b), and accordingly, the compensation value calculated based on the linear functions Func1_1 and Func1_2 may be relatively large compared to the case of FIG. 7(a). Alternatively, when threshold voltage distributions have an asymmetrical shape as illustrated in FIG. 5, a valley height may be calculated as large, and in this case, because the actual location of a valley of the threshold voltage distributions may vary greatly, a compensation value may be calculated to be relatively large. In some example embodiments, table information including a compensation value corresponding to a valley height may be stored in a memory device, and the compensation value may be calculated based on the calculated valley height and the table information.

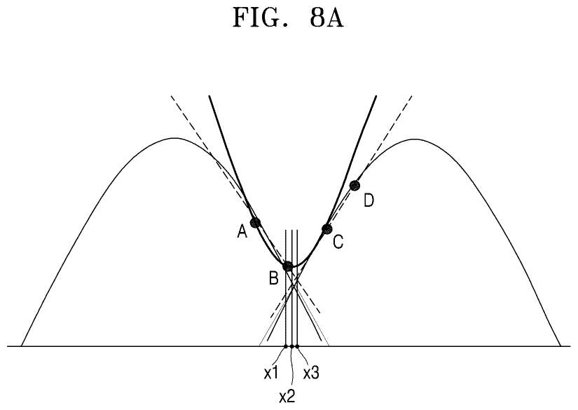

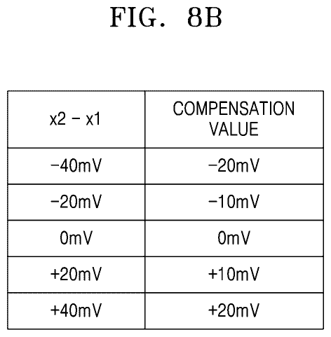

FIGS. 8A and 8B illustrate an example of calculating a compensation value by using the x value of coordinates of a crossing point.

When a valley between threshold voltage distributions is searched for by using a high-order function, the search result may be deteriorated due to various causes. For example, when the threshold voltage distributions have an asymmetric shape or the locations of read levels selected for the optimal read level is not appropriate, the accuracy of the location of the valley which has been determined by using the high-order function may degrade.

As illustrated in FIGS. 8A and 8B, according to the present embodiment, the compensation value may be calculated based on the x value of a crossing point of the linear functions. For example, when, by using a plurality of read levels and the first, second, third, and fourth coordinates A, B, C, and D corresponding thereto, a quadratic function is modeled based on read levels corresponding to the first, second, and third coordinates A, B, and C, and two linear functions are modeled based on the read levels corresponding to the first, second, third, and fourth coordinates A, B, C, and D, the read level calculated by using the quadratic function may have a value corresponding to x1. On the other hand, the x value of the crossing point of the two linear functions may have a value corresponding to x2.

FIG. 8B illustrates an example of table information for calculating a compensation value based on the x value of the crossing point of linear functions. In some example embodiments, the compensation value may be calculated based on a difference value between a read level x1 calculated by using the quadratic function and a read level x2 calculated from the crossing point of the linear functions, and in the example of FIG. 8B, a case is provided in which a value corresponding to half of a difference value between the read level x1 and the read level x2 is calculated as the compensation value. An optimal read level x3 may be calculated by adding the calculated compensation value to the read level x1 calculated by using the quadratic function. As an example, when the compensation value has a positive (+) value, the level shifted to the right from the read level x1 calculated by using the quadratic function may correspond to the optimal read level x3, and when the compensation value has a negative (−) value, the level shifted to the left from the read level x1 calculated by using the quadratic function may correspond to the optimal read level x3.

In some example embodiments, a case in which the compensation value corresponds to half of the difference value between the read level x1 and the read level x2 is illustrated. However, example embodiments are not limited thereto, and the compensation value may also be calculated by using various calculations by using the read level x1 and the read level x2.

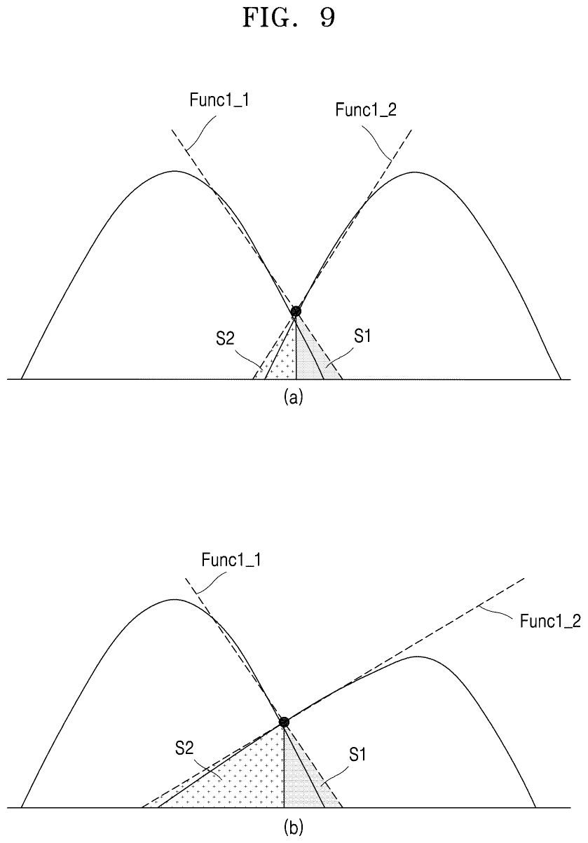

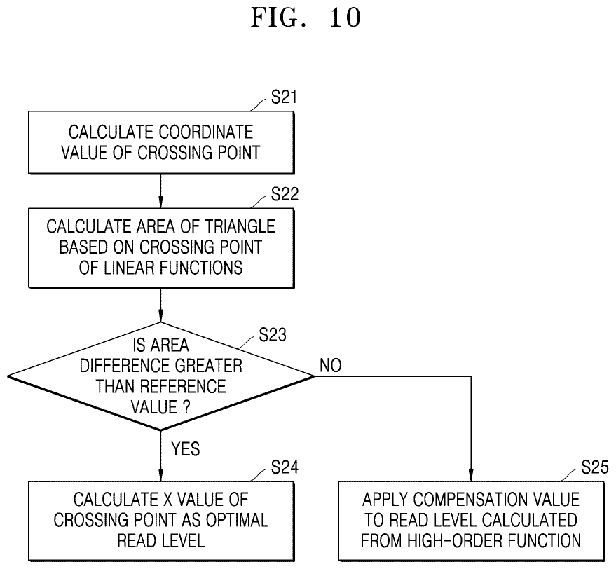

FIGS. 9 and 10 illustrate cases in which the optimal read level is calculated based on areas of shapes calculated by using graphs of linear functions.

As illustrated in FIG. 9, a triangle may be deduced by using a crossing point and the x axis of two linear functions. In this case, as illustrated in FIG. 9(A), when the threshold voltage distributions have a symmetrical shape, the areas of the two triangles S1 and S2 deduced from two linear functions may be the same as or similar to each other. On the other hand, as illustrated in FIG. 9(B), when the threshold voltage distributions have an asymmetrical shape, the areas of the two triangles S1 and S2 deduced from the two linear functions may be different, or the difference value between the areas of the two triangles S1 and S2 may exceed a certain reference value.

According to some example embodiments described above, when the threshold voltage distributions have an asymmetric shape, the accuracy of the read level calculated based on a high-order function such as a quadratic function may be low. In some example embodiments, a method of calculating the optimal read level based on a difference value between the areas of the two triangles S1 and S2 may be set in a different manner.

Referring to FIGS. 9 and 10, coordinate values of crossing points of linear functions may be calculated (S21), and the areas of the two triangles S1 and S2 may be calculated based on the crossing points of linear functions (S22). In addition, the difference value between the areas of the triangles S1 and S2 may be calculated, and the difference value between the areas may be compared to a certain reference value (S23).

As a result of the comparison, when the difference value of the areas is greater than the reference value, it may be determined that the accuracy of the read level calculated based on the high-order function is low, and the x value of the crossing point of the linear functions may be calculated as the optimal read level, without using the read level as information for calculating the optimal read level (S24). On the other hand, when the difference value of the areas is less than the reference value, the optimal read level may be calculated by using the read level calculated based on the high-order function, and for example, the optimal read level may be calculated by applying the compensation value calculated based on the linear functions to the read level calculated from the high-order function according to the embodiments described above (S25).

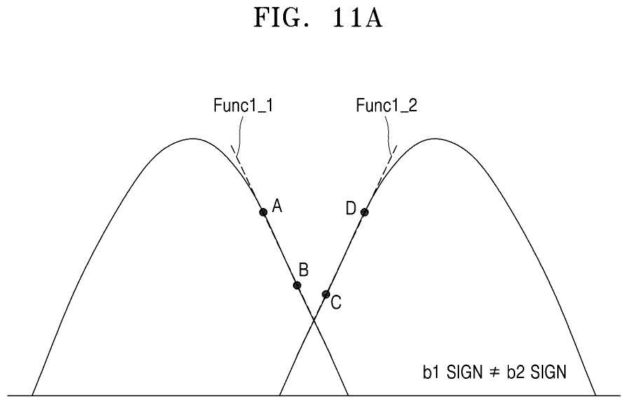

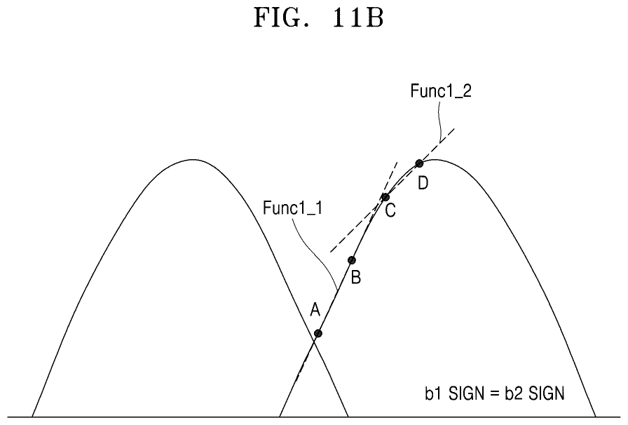

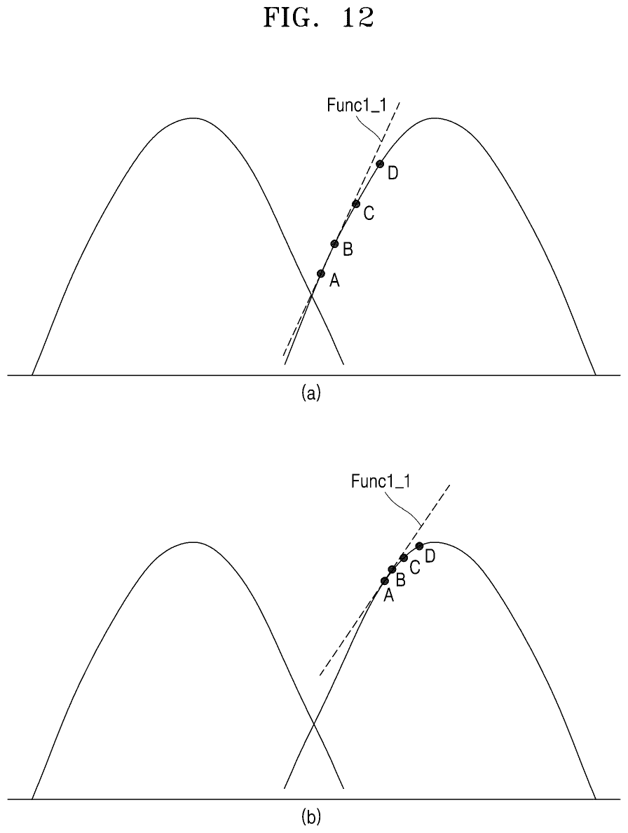

FIGS. 11A, 11B, and 12 are diagrams of examples of using signs and absolute values of slopes of linear functions in calculating the optimal read level.

According to some example embodiments described above, two linear functions Func1_1 and Func1_2 may be modeled from the counting values respectively corresponding to the plurality of read levels. The sign and absolute value of the slope of each of the linear functions Func1_1 and Func1_2 may be calculated according to a modeling result. FIG. 11A illustrates an example in which the sign of a slope b1 of one linear function Func1_1 is different from the sign of a slope b2 of the other linear function Func1_2, and FIG. 11B illustrates an example in which the sign of the slope b1 of one linear function Func1_1 is the same as the sign of the slope b2 of the other linear function Func1_2.

To increase the calculation accuracy of the optimal read level, the counting values corresponding to read levels located on first and second sides, or both sides, of the valley between the threshold voltage distributions may need to be calculated. In this case, the read levels used to calculate the counting values may be selected within a search area having a certain level range, and when the search area is not properly set, the accuracy of the calculated optimal read level may deteriorate. As illustrated in FIG. 10A, when the signs of the slopes of the two linear functions Func1_1 and Func1_2 are different from each other, it may be determined that the search area is appropriately set. On the other hand, as illustrated in FIG. 10B, when the slope b1 of one linear function Func1_1 is the same as the slope b2 of the other linear function Func1_2, it may be determined that the search area for calculating the optimal read level is not properly set, and an operation for changing the search area may be performed. A memory device may re-calculate a plurality of counting values respectively corresponding to a plurality of read levels within the range of the changed search area, and may perform again a modeling operation of the cell count function and a compensation operation for calculating the optimal read level according to the embodiments described above.

For example, when the signs of the slopes b1 and b2 are positive (+) and the same as each other, it may be determined that the existing search area is located on the right side with respect to the valley between the threshold voltage distributions, and accordingly, the range of the search area may be changed in the negative (−) direction. On the other hand, when the signs of the slopes b1 and b2 are negative (−) and the same as each other, it may be determined that the existing search area is located on the left side with respect to the valley between the threshold voltage distributions, and the range of the search area may be changed in the positive (+) direction.

FIG. 12 illustrates a case in which the absolute value of the slope is used to change the search area, and for example, the absolute value of the slope of the linear function modeled by using two read levels adjacent to the valley may be determined. For example, as illustrated in FIG. 12, when the slopes of linear functions all have positive (+) values, the absolute value of the slope of the linear function modeled, by using two coordinates A and B adjacent to the valley (or, having relatively low read levels), may be determined. Although not illustrated in FIG. 12, when the slopes of the linear functions all have negative (−) values, the absolute value of the slope of the linear function modeled, by using the coordinates adjacent to the valley (or, having relatively high read levels), may be determined.

FIG. 12(a) illustrates a case in which the absolute value of the slope is relatively large, and FIG. 12b) illustrates a case in which the absolute value of the slope is relatively small, compared to the case of FIG. 12(b). When the absolute value of the slope is relatively large, the degree of shift in which the search area is changed in the negative (−) direction may have a relatively small value. On the other hand, when the absolute value of the slope has a relatively small value, the difference value between the level range of the existing search area and the read level corresponding to the location of the valley may be large, and accordingly, the degree of shift in which the search area is changed in the negative (−) direction may have a relatively large value.

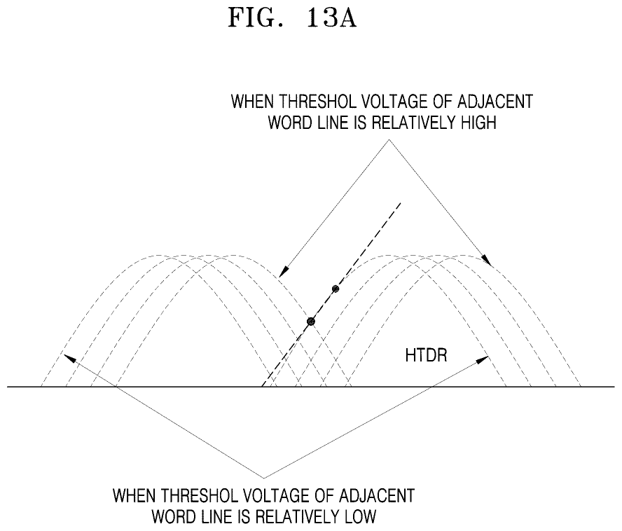

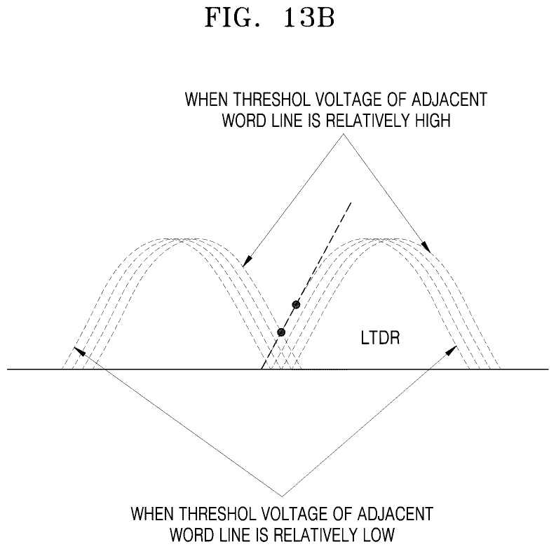

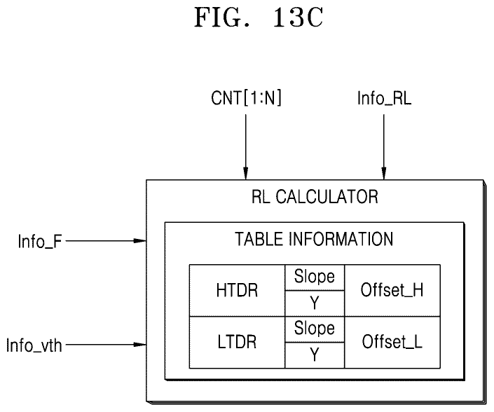

FIGS. 13A, 13B, and 13C are diagrams of examples of compensation operations based on the valley heights and slopes of the linear functions.

The threshold voltage distribution may deteriorate under various conditions, and for example, deterioration characteristics of the threshold voltage distribution in a high temperature environment may be different from those in a low temperature environment. For example, the threshold voltage level of memory cells of any one word line may vary due to charge loss depending on the threshold voltage distribution of an adjacent word line. For example, the amount of charge loss may be relatively large in a high temperature environment, while the amount of charge loss may be relatively small in a low temperature environment.

In FIGS. 13A and 13B, examples of deterioration of threshold voltage distribution in high and low temperature environments, respectively, and when the threshold voltage level of the adjacent word line is relatively low, the charge loss to the adjacent word line increases, the variation of the threshold voltage distribution may be relatively large. In addition, as the threshold voltage distribution deteriorates, the valley height between the threshold voltage distributions may be calculated as relatively large. For example, the valley height may be determined, based on the y value of the crossing point of two linear functions, and when the valley height is greater than a certain reference value, it may be determined that the threshold voltage distribution deteriorates.

Alternatively or additionally, at least one slope (for example, the absolute value of the slope) of the two linear functions may be determined, and based on the determination result, a method of compensating the read level may be selected. For example, as illustrated in FIG. 13A, when the valley height calculated based on the crossing point of the linear functions is greater than a certain reference value, the slope b1 is gradual, or the absolute value of the slope is less than a particular reference value, it may be determined that the threshold voltage distribution of the memory cells has been changed in a high temperature environment, and a compensation method corresponding thereto may be selected. On the other hand, when the calculated valley height is greater than a certain reference value as illustrated in FIG. 13B, the slope b1 is steep, or the absolute value of the slope is greater than the particular reference value, it may be determined that the threshold voltage distribution of the memory cells has been changed in a low temperature environment, and a compensation method corresponding thereto may be selected.

FIG. 13C is a diagram of an example of calculating the optimal read level in a data recovery read (DRR) operation.

When the UECC occurs in a read operation on the memory cells connected to a particular word line (for example, a first word line), based on the DRR technique, the memory controller may output, to the memory device, a predefined command indicating the calculation of the read level in the DRR operation. The DRR technique may be defined in various ways, and for example, in calculating the read level in the DRR operation, a method of reading data of at least one second word line adjacent to the first word line, and calculating the read level of the first word line, based on determining the characteristics of the threshold voltage distributions of the second word line, may be defined as the DRR technique. For example, the optimal read level in the DRR operation may be calculated, by applying one or more offset values calculated by using the DRR technique to the reference read level for the first word line, with respect to the reference read level of the first word line.

The memory device may, in response to a predefined command from the memory controller, determine a threshold voltage distribution of memory cells read from the second word line, and may calculate one or more offset values, based on the determined threshold voltage distribution. In addition, according to embodiments, the reference read level may be calculated based on the valley search result by using the high-order function modeled with respect to the first word line, the compensation value may be calculated based on a plurality of linear functions modeled with respect to the first word line, and the accuracy of the reference read level may be improved by applying the calculated compensation value to the reference read level. Alternatively or additionally, by applying the offset values calculated, based on the threshold voltage distribution of the second word line to the reference read level, the optimal read level in the DRR operation may be calculated. In this case, in applying the compensation value, by applying the offset value differently according to an environment in which the threshold voltage distribution is deteriorated, for example, a high temperature or low temperature environment, the calculation accuracy of the optimal read level in the DRR operation may be improved.

In some example embodiments, the read level calculator may model a high-order function and at least two linear functions, based on the read level information Info_RL and the counting value CNT[1:N], and in addition, may calculate the optimal read level in the DRR operation, based on the threshold voltage distribution information Info_vth of the second word line and the calculation information Info_F of linear functions with respect to the first word line. For example, the read level calculator may calculate the reference read level in the DRR operation with high accuracy, by applying the compensation value based on linear functions according to some example embodiments described above.

The read level calculator may include table information including offset values used in the DRR technique, and the table information may include the first entry HTDR having a value related to the high temperature environment and the second entry LTDR having a value related to the low temperature environment. In addition, in each entry, offset values corresponding to the valley height Y and/or the slope Slope may be stored as table information. For example, the first entry HTDR having a value related to the high temperature environment may include information about the first offset value Offset_H, and the second entry LTDR having a value related to the low temperature environment may include information about the second offset value Offset_L.

When the slope value of the linear function is relatively small, the read level calculator may calculate an offset value corresponding to the threshold voltage distribution of adjacent word lines by referring to table information about the first entry HTDR, and when the slope value of the linear function is relatively large, may calculate an offset value corresponding to the threshold voltage distribution of adjacent word lines by referring to table information about the second entry LTDR.

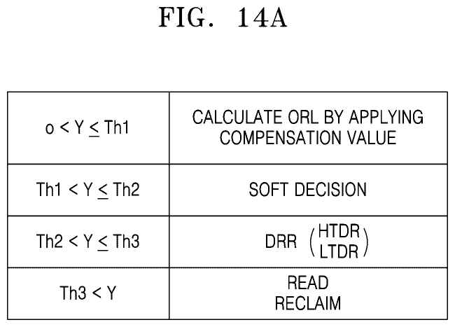

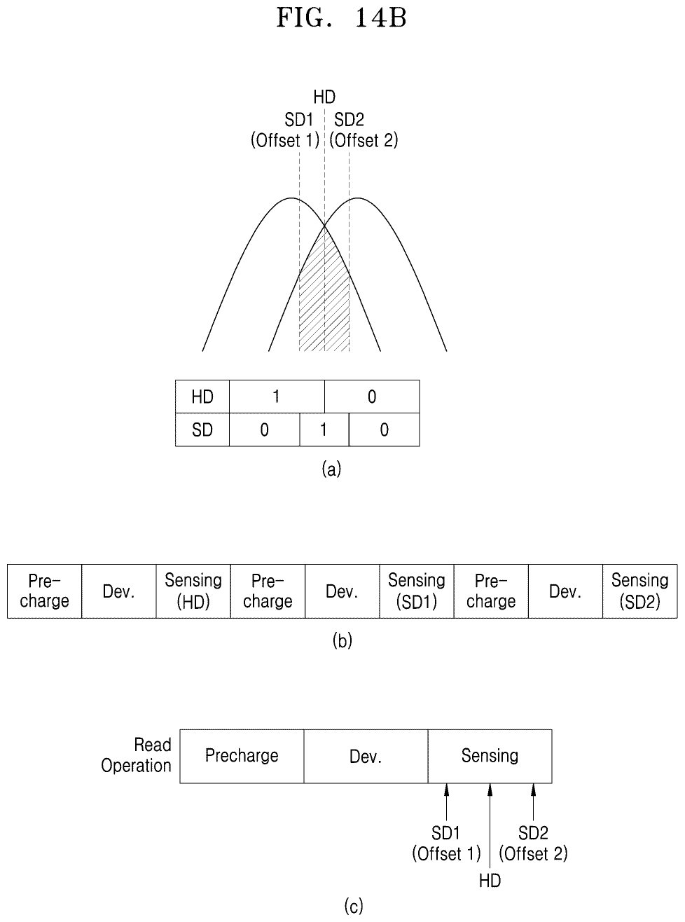

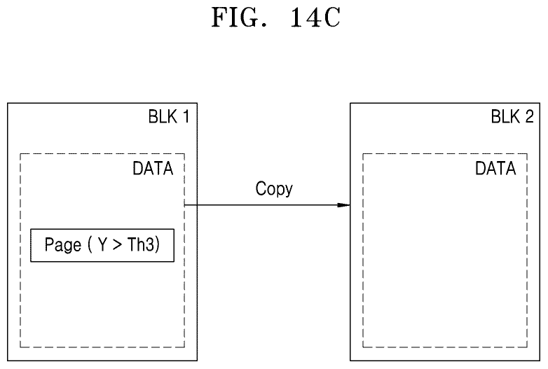

FIGS. 14A, 14B, and 14C illustrate tables representing examples in which a data recovery policy is selectively applied according to information about a linear function.

According to some example embodiments described above, when the UECC occurs in the data read operation, a series of operations for calculating an optimal read level, based on a plurality of read levels and the counting values corresponding thereto may be performed. In this case, the Y value of the crossing point of the linear functions may have a value related to the valley height, and when the valley height is large, it may be determined that the threshold voltage distribution is greatly deteriorated. In some example embodiments, in performing a data recovery operation according to the occurrence of the UECC, various types of recovery policies may be selectively performed, based on determination of the size of the valley height.

For example, when the Y value corresponding to the valley height is less than or equal to a first threshold value Th1, it may be determined that the degree of deterioration is relatively small, and according to the embodiments described above, the compensation value may be calculated based on the crossing point of the linear functions, and the optimal read level may be calculated based on the compensation value. For example, the memory device may calculate an optimal read level ORL by applying the compensation value to the read level calculated by using the high-order function.

On the other hand, when the Y value is greater than the first threshold value Th1 and less than a second threshold value Th2, the degree of deterioration may be determined to be greater than the case in which the Y value is less than the first threshold value Th1, and other data recovery operations may be performed under the control of the memory controller, without performing the re-read operation using the optimal read level in the memory device. For example, a flag indicating the degree of deterioration based on the Y value may be generated and output to the memory controller, and in the example of FIG. 14A, soft decision SD data is read under the control of the memory controller.

Referring to FIG. 14B, the memory controller may perform a control operation for reading SD data to a cell area where the UECC has occurred. As illustrated in FIG. 14B(a), data determined based on the normal read level may correspond to hard decision (HD) data, and data determined based on the offset level may correspond to the SD data. The offset level may include a first offset level Offset 1 having a level less than a normal read level by a first offset, and a second offset level Offset 2 having a level greater than the normal read level by a second offset. For example, the HD data of a memory cell having a lower threshold voltage than the normal read level may have a value of “1”, and the HD data of a memory cell having a higher threshold voltage than the normal read level may have a value of “0”. In addition, the SD data of a memory cell having a threshold voltage lower than the first offset level Offset 1 or higher than the second offset level Offset 2 may have a value of “0”, whereas the SD data of a memory cell having a threshold voltage between the first offset level Offset 1 and the second offset level Offset 2 may have a value of “1”. The SD data may include information indicating whether a memory cell has a strong error or a weak error, and as an error correction operation is performed based on the HD data and the SD data, the correction capability may be improved compared to the case of correcting an error by using only the HD data.

FIG. 14B(b) illustrates a method of generating the SD data based on a plurality of read operations, and for example, the SD data may be generated by applying read voltages having different levels to the word line in the plurality of read operations. For example, the HD data may be generated by using a first read operation of applying a word line voltage having a normal read level, and the SD data may be generated, based on a first SD data SD1 determined by using a second read operation of applying the word line voltage corresponding to the first offset level Offset 1, and a second SD data SD2 determined by using a third read operation of applying the word line voltage corresponding to the second offset level Offset 2.

FIG. 14B(c) illustrates a method of generating the HD data and the SD data together by using one read operation, and the corresponding method may be referred to as a fast SD operation. In the case of the fast SD operation, a sensing operation may be performed at at least two different sensing timings to determine the HD data and the SD data in a sensing period. According to the sensing timings, a value of data, based on the first offset level Offset 1, the normal read level, and the second offset level Offset 2 may be determined, and the HD data and the SD data may be generated by using the sensing operations. As in the example described above, the memory controller may correct an error occurring in the data, by performing a decoding operation with improved correction capability by using the HD data and the SD data together.

On the other hand, although not illustrated in FIG. 14A, the degree of deterioration based on the Y value may be further subdivided and determined, and depending on the determination result, a generation operation of the SD data according to a general method and a generation operation of the SD data according to a fast SD method may also be selectively performed. In addition, the UECC may be a result due to an error generated in pre-read HD data, and in some example embodiments, as the Y value exceeds the first threshold value Th1, the HD data may be read again under the control of the memory controller, the HD data and the SD data may be provided to the memory controller together, or the SD data may be selectively read to be provided to the memory controller.

Referring to FIG. 14A again, when the Y value is greater than the second threshold value Th2 and less than or equal to a third threshold value Th3, it may be determined that the degree of deterioration is greater than the case where the Y value is less than the second threshold value Th2, and other type of data recovery operation may be performed under the control of the memory controller. For example, in the example of FIG. 14A, the case where the optimal read level is calculated by using the DRR technique under the control of the memory controller is illustrated. According to the embodiment described above, an environment in which the threshold voltage distribution is deteriorated (for example, a high or low temperature environment) may be determined, based on information related to the valley height and the slope of the linear functions, and the compensation value for calculating the optimal read level may be determined, based on entry information of a table corresponding to the determined environment.

On the other hand, when the Y value is greater than the third threshold value Th3, it may be determined that a cell block including the cell area storing the corresponding data has deteriorated, and as illustrated in FIG. 14C, a read reclaim operation of copying the data of the corresponding cell block to another cell block having good characteristics, based on control by the memory controller, may be performed. In some example embodiments, a flag indicating the degree of deterioration may be output to a memory controller, and the memory controller may register a corresponding cell block as a cell block to be read reclaimed.

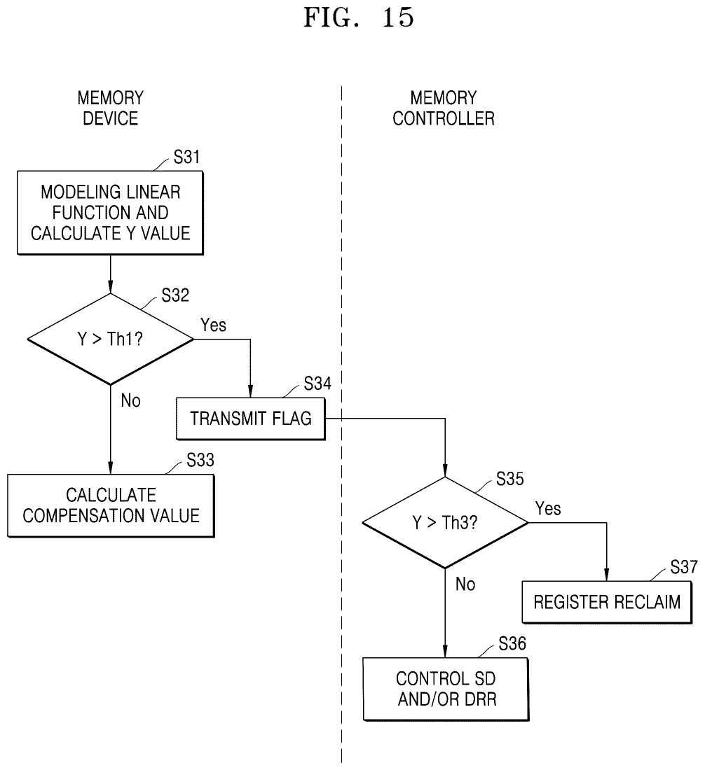

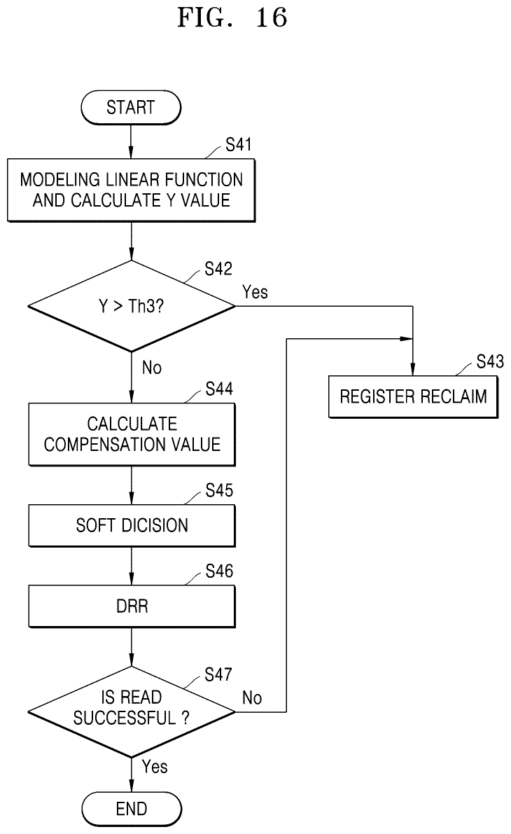

FIGS. 15 and 16 are flowcharts of examples of operations of the memory system 10, according to some example embodiments illustrated in FIGS. 14A, 14B, and 14C.

As illustrated in FIG. 15, the memory device may model linear functions by using a plurality of read levels and counting values corresponding thereto, and calculate the Y value corresponding to the valley height by using the crossing point of the linear functions (S31). The calculated Y value may be compared to the first threshold value Th1 (S32), and when the Y value is not greater than the first threshold Th1, it may be determined that the degree of deterioration is relatively small, and accordingly, the compensation value for calculating the optimal read level in the memory device may be calculated (S33). On the other hand, when it is determined that the Y value is greater than the first threshold value Th1, the memory device may transmit a flag indicating the degree of deterioration of the threshold voltage distributions of the memory cells to the memory controller (S34), and the memory controller may determine whether the Y value is greater than the third threshold value Th3 based on reference to the flag (S25). As a result of the determination, when the Y value is not greater than the third threshold value Th3, the memory controller may perform a control operation for controlling read of the SD data or calculating the optimal read level based on the DRR technique (S36). On the other hand, when the Y value is greater than the third threshold value Th3, the memory controller may register the corresponding cell block as a cell block to be read reclaimed.

On the other hand, referring to FIG. 16, linear functions may be modeled according to the embodiments described above, and the Y value corresponding to the valley height may be calculated (S41), and whether the corresponding cell area corresponds to the read reclaim registration target may be determined by comparing the Y value to the third threshold value Th3 (S42). When the Y value is greater than the third threshold value Th3, the cell area including a page (or the word line) where the error has occurred may be registered as the read reclaim target (S43).

Although the corresponding cell area is registered as the read reclaim target, an operation of calculating the optimal read level and the re-read operation may be performed. For example, a read operation using a plurality of read levels may be performed on a page in which an error has occurred, according to the embodiments described above, and the compensation value may be calculated based on the modeling result of a plurality of linear functions along with modeling of the high-order function (S44). When the UECC occurs even in data read by using the optimal read level to which the compensation value is applied, the SD data read operation (S45) and the optimal read level calculation operation (S46) based on the DRR technique may be sequentially performed as various data recovery operations.

By using the data recovery operations described above, it may be determined whether read has been successful (S47), and when read is successful, the corresponding read operation may be terminated. On the other hand, when read fails even by using the data recovery operations, the corresponding cell area may be registered as the read reclaim target (S43). According to the embodiment, even when the Y value is greater than the third threshold value Th3, an error correction may be attempted by performing a data re-read operation, and when it is determined that the deterioration of the cell area is high because the Y value is greater than the third threshold value Th3, the reliability of data may be secured by registering the cell area as the read reclaim target in advance even when the read has been successful.

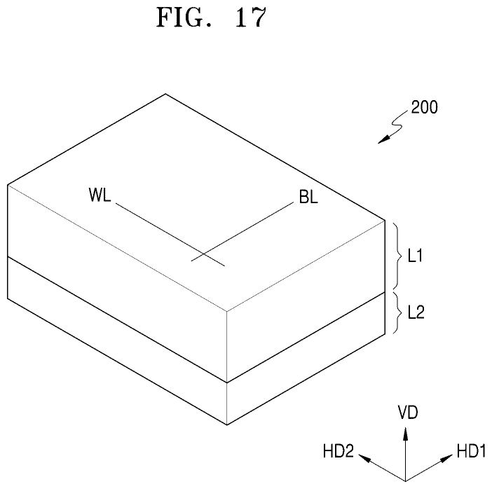

FIG. 17 is a schematic structure of the memory device 200 according to some example embodiments. Referring to FIGS. 1 and 17, the memory device 200 may include a first semiconductor layer L1 and a second semiconductor layer L2, and the first semiconductor layer L1 may be stacked in a vertical direction VD with respect to the second semiconductor layer L2. The second semiconductor layer L2 may be arranged under the first semiconductor layer L1 in the vertical direction VD. In some example embodiments, the memory cell array 210 may be formed in the first semiconductor layer L1, and a periphery circuit may be formed in the second semiconductor layer L2. Accordingly, the memory device 200 may have a structure in which the memory cell array 210 is arranged over the peripheral circuit, that is, a cell over periphery (COP) structure and/or a bonding VNAND (B-VNAND) structure.

In the first semiconductor layer L1, bit lines BL may extend in a first direction HD1, and word lines WL may extend in a second direction HD2. The second semiconductor layer L2 may include a substrate, and a peripheral circuit may be formed on the second semiconductor layer L2 by forming a pattern for wiring semiconductor devices such as transistors and devices on the substrate. In some example embodiments, when the memory device 200 has the COP structure, after the periphery circuit is formed in the second semiconductor layer L2, the first semiconductor layer L1 including the memory cell array 210 may be formed, and patterns for electrically connecting the word lines WLs and the bit lines BLs of the memory cell array 210 to the periphery circuit formed in the second semiconductor layer L2 may be formed. In some example embodiments, when the memory device 200 has a B-VNAND structure, after the periphery circuit and lower bonding pads are formed in the second semiconductor layer L2, and the memory cell array 210 and upper bonding pads are formed in the first semiconductor layer L1, the upper bonding pads in the first semiconductor layer L1 may be connected to the lower bonding pads in the second semiconductor layer L2 in a bonding manner.

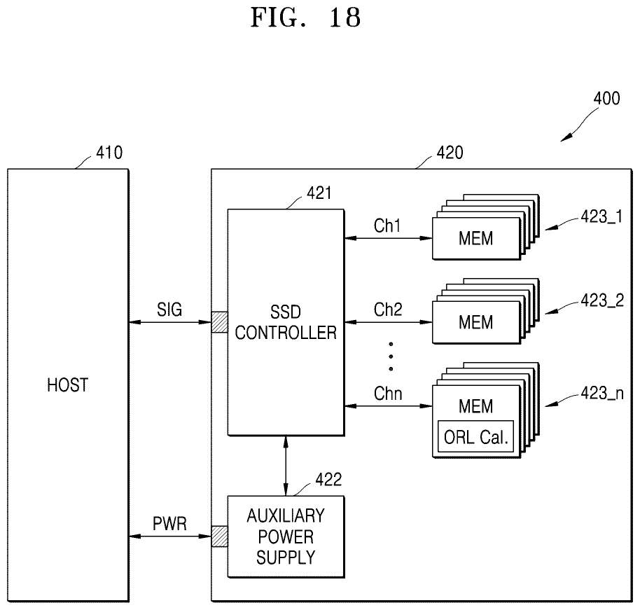

FIG. 18 is a block diagram of an example in which the memory system 10 according to the embodiments is applied to an SSD system 400.

Referring to FIG. 18, the SSD system 400 may include a host 410 and an SSD 420. The SSD 420 may exchange a signal SIG with the host 410 via a signal connector, and receive power PWR via a power connector. The SSD 420 may include an SSD controller 421, an auxiliary power supply 422, and non-volatile memory devices 423_1 through 423_n. The non-volatile memory devices 423_1 through 423_n may include NAND flash memories. In this case, the SSD 420 may be implemented by using the embodiments described above with reference to FIGS. 1 through 17. In other words, each of the non-volatile memory devices 423_1 through 423_n may include an optimal read level ORL calculation module according to the embodiments described above, and the optimal read level ORL calculation module may model a high-order function and two or more linear functions, based on a plurality of read levels and the counting values corresponding thereto. In addition, the optimal read level ORL calculation module may calculate the compensation value based on various operations, according to the embodiments described above, and may improve read performance and reliability of data by calculating the optimal read level based on the compensation value.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc..

While inventive concepts have been particularly shown and described with reference to some example embodiments thereof, it will be understood that various change in form and details may be made therein without departing from the spirit and scope of the following claims. Additionally, example embodiments are not necessarily mutually exclusive with one another. For example, some example embodiments may include one or more features described with reference to one or more figures, and may also include one or more other features described with reference to one or more other figures.

What is claimed is:

1. A memory device comprising:
a memory cell array including a plurality of cell areas, wherein memory cells of each of the cell areas are configured to be in a plurality of threshold voltage distributions; and
a control logic configured to control a calculation operation for an appropriate read level, based on searching for a valley of the threshold voltage distributions, in response to an error occurring in a read operation on the cell areas,
wherein the control logic is configured to,
calculate first through N^{th} counting values respectively corresponding to first through N^{th} read levels based on a counting operation on data read by using a plurality of read levels,
calculate a crossing point of at least two linear functions modeled by substituting the first through N^{th} read levels as inputs and the first through N^{th} counting values as outputs, and
calculate the appropriate read level based on at least one of the read level and a valley height corresponding to a coordinate value of the crossing point (where N is an integer equal to or greater than 3).

2. The memory device of claim 1, wherein,
the counting values comprise first through fourth counting values respectively corresponding to first through fourth read levels,
the control logic is configured to model one linear function based on the first and second counting values respectively corresponding to the first and second read levels, and to model at least one other linear function based on the third and fourth counting values respectively corresponding to the third and fourth read levels, and
the control logic is configured to calculate the crossing point of two modeled linear functions.

3. The memory device of claim 2,
wherein the control logic is configured to,
further model an M^{th}-order function based on at least some of the first through fourth read levels and the counting values corresponding thereto (where M is an integer equal to or greater than 2), and
calculate the appropriate read level by applying a compensation value calculated, based on at least one of the read level and the valley height corresponding to the coordinate value of the crossing point, to the read level calculated by using the M^{th}-order function.

4. The memory device of claim 3, wherein
the control logic is configured to calculate the compensation value based on the valley height corresponding to the coordinate value of the crossing point, and
the compensation value increases as a value of the valley height increases.

5. The memory device of claim 1,
wherein the control logic is configured to
select the first through N^{th} read levels for modeling the at least two linear functions in a search area having a certain level range, and
determine information related to a slope of each of the at least two linear functions, and change a level range of the search area, based on the determined information.

6. The memory device of claim 5,
wherein the control logic is configured to,
change the search area, in response to a slope of one linear function modeled based on read levels having relatively low levels among the first through N^{th} read levels being identical to a sign of the slope of another linear function modeled, based on the read levels having relatively high levels among the first through N^{th} read levels.

7. The memory device of claim 1,
wherein the control logic is configured to,
in response to the error occurring in a first cell area among the cell areas, read data of a second cell area including a word line adjacent to the first cell area, based on control by a memory controller, and calculate a read level of the first cell area, based on the threshold voltage distributions of memory cells of the second cell area, and
calculate a compensation value based on the coordinate value of the crossing point calculated for the first area, and calculate the appropriate read level of the first area by applying the calculated compensation value to the read level calculated, based on the threshold voltage distributions of the second cell area.

8. The memory device of claim 7,
wherein the control logic comprises a first table configured to store information about the compensation values under a high temperature environment condition, and a second table configured to store information about the compensation values under a low temperature environment condition,
in response to an absolute value of a slope of at least one linear function being less than a second reference value, the control logic is configured to calculate the compensation value with reference to the first table, and
in response to the absolute value of the slope of the at least one linear function being equal to or greater than the second reference value, the control logic is configured calculate the compensation value with reference to the second table.

9. The memory device of claim 1,
wherein the control logic is configured to generate a flag indicating a degree of deterioration of the threshold voltage distributions, based on comparison of the valley height to one or more threshold values, and
wherein the memory device is configured to output the flag to a memory controller.

10. The memory device of claim 1, wherein,
in response to an uncorrectable error correction code (UECC) occurring in the read operation, the control logic is configured to perform an operation of calculating the appropriate read level is performed in response to a command from a memory controller.

11. An operating method of a memory device, the operating method comprising:
in response to an error existing in data read from a first cell area of a memory cell array, entering a valley search mode based on control by a memory controller;
in relation to the first cell area and based on a counting operation on the data read by using a plurality of read levels, calculating first through fourth counting values respectively corresponding to first through fourth read levels;
modeling an M^{th}-order function based on at least some of the first through fourth read levels and the counting values corresponding thereto (where M is an integer greater than or equal to 2);
modeling one linear function based on the first and second counting values respectively corresponding to the first and second read levels,
modeling at least one other linear function based on the third and fourth counting values respectively corresponding to the third and fourth read levels; and
calculating an appropriate read level for the first cell area, by applying a compensation value to a read level calculated by using the M^{th}-order function, the compensation value calculated using the one linear function and the at least one other linear function.

12. The operating method of claim 11, further comprising:
performing a re-reading operation on the first cell area by using the calculated appropriate read level.

13. The operating method of claim 11,
wherein the read level calculated by using the M^{th}-order function is a read level corresponding to an input to cause an output of the M^{th}-order function to have a value based on a minimum value, and
wherein the compensation value is calculated based on at least one of the read level and a valley height corresponding to a coordinate value of a crossing point of the one linear function and the at least one other linear function.

14. The operating method of claim 13, wherein the M^{th}-order function is based on a quadratic function modeled, and is based on three read levels selected from the first through fourth read levels and the counting values corresponding thereto.

15. The operating method of claim 13, wherein the memory device further comprises a table configured to store the compensation value corresponding to the valley height.

16. The operating method of claim 13, further comprising:
outputting, to the memory controller, a flag indicating a degree of deterioration of the first cell area based on a value of the valley height; and
as a value of the valley height exceeds a certain threshold value, outputting soft decision (SD) data determined by using at least one offset level to the memory controller and based on control by the memory controller.

17. The operating method of claim 11, wherein,
in response to an uncorrectable error correction code (UECC) occurring in a read operation on the first cell area, the method further includes calculating the appropriate read level in response to a command from the memory controller.

18. A memory device comprising:
a memory cell array including a plurality of cell areas, wherein memory cells of each of the cell areas are configured to be in a plurality of threshold voltage distributions; and
in response to an error occurring in a read operation on the cell areas, a control logic configured to control a calculation operation for an appropriate read level, based on searching for a valley of the threshold voltage distributions,
wherein the control logic is configured to,
calculate first through N^{th} counting values respectively corresponding to first through N^{th} read levels, based on a counting operation on data read by using a plurality of read levels, and
output a flag to a memory controller, based on a coordinate value of a crossing point of at least two linear functions modeled by substituting the first through N^{th} read levels as inputs and the first through N^{th} counting values as outputs (where N is an integer equal to or greater than 3), the flag indicating a degree of deterioration of the threshold voltage distributions.

19. The memory device of claim 18,
wherein the control logic is configured to generate the flag based on comparison of a value of a valley height to one or more threshold values, the valley height corresponding to the coordinate value of the crossing point.

20. The memory device of claim 19, wherein,
in response to the degree of deterioration being less than a first threshold value, the control logic is configured to calculate a read level from an M^{th}-order function modeled, and based on at least some of the first through N^{th} read levels and counting values corresponding thereto, the control logic is configured to calculate the appropriate read level of the cell areas by applying calculated compensation value based on the coordinate value of the crossing point to the read level, and
in response to the degree of deterioration exceeding a second threshold value greater than the first threshold value, the control logic is configured to perform, based on control by the memory controller, a read reclaim operation of copying data of a cell block where the error occurs to another cell block.
